(19) United States
(12) Patent Application Publication
(10) Pub. No.: US 2024/0412946 A1
(43) Pub. Date: Dec. 12, 2024

(54) CHARGED PARTICLE BEAM WRITING APPARATUS AND CHARGED PARTICLE BEAM WRITING METHOD

(71) Applicant: NuFlare Technology, Inc., Yokohama-shi (JP)

(72) Inventor: Kensuke KOGA, Yokohama-shi (JP)

(73) Assignee: NuFlare Technology, Inc., Yokohama-shi (JP)

(21) Appl. No.: 18/666,906

(22) Filed: May 17, 2024

(30) Foreign Application Priority Data
Jun. 8, 2023 (JP) 2023-094908

(51) Int. Cl. H01J 37/317; G03F 7/00; H01J 37/18; H01J 37/304

(52) U.S. Cl. CPC H01J 37/3177; H01J 37/18; H01J 37/304; G03F 7/70925

(57) ABSTRACT

In one embodiment, an apparatus is for writing a pattern by irradiating a substrate as a writing target in a chamber with a charged particle beam. The apparatus includes a supply device supplying a cleaning gas to the chamber, a vacuum pump discharging a gas from the chamber, a pressure sensor detecting a pressure in the chamber, and a control device obtaining a detection value of the pressure sensor and controlling the supply device so that the pressure in the chamber reaches a first target value. When adjusting the charged particle beam with which the substrate is irradiated, the control device further controls the supply device so that the pressure in the chamber reaches a second target value different from the first target value.

### CROSS REFERENCE TO RELATED APPLICATION

This application is based upon and claims benefit of priority from the Japanese Patent Application No. 2023-094908, filed on Jun. 8, 2023, the entire contents of which are incorporated herein by reference.

### FIELD

The present invention relates to a charged particle beam writing apparatus and a charged particle beam writing method.

### BACKGROUND

As LSI circuits are increasing in density, the required linewidths of circuits included in semiconductor devices become finer year by year. To form a desired circuit pattern on a semiconductor device, a method is employed in which a high-precision original pattern (i.e., a mask, or also particularly called reticle, which is used in a stepper or a scanner) formed on quartz is transferred to a wafer in a reduced manner by using a reduced-projection exposure apparatus. The high-precision original pattern is written by using an electron-beam writing apparatus, in which a so-called electron-beam lithography technique is employed.

In an electron beam writing apparatus, a pattern is written by irradiating a desired position with an electron beam by deflecting the electron beam by a deflector. Along with the use of the writing apparatus, hydrocarbon-based pollution materials (contamination) adhere to electronic optical system components such as a deflector. When an electric charge is accumulated in the pollution materials, a problem arises in that a beam drift phenomenon occurs, that is, the irradiation position of the electron beam deviates.

A technique is known in which a cleaning gas such as ozone gas is introduced into the column of a writing apparatus, and electronic optical system components are maintained clean while writing is performed. For example, the ozone introduced into the column and electron beams are brought into collision to separate the ozone into oxygen and active oxygen. The separated active oxygen and pollution materials are reacted to convert them to carbon monoxide gas which is exhausted, thereby reducing the pollution materials that adhere to electronic optical system components.

Fluctuation of the pressure in the column due to introduction of the cleaning gas causes focus deviation of the electron beam, thus to cope with this, the pressure in the column is controlled at constant. In a conventional writing apparatus, when the gas generated from the components in the apparatus gradually decreases with use, the amount of introduction of ozone gas is gradually increased to maintain the pressure in the column.

However, in such a conventional writing apparatus, the pressure in the column is always in a high state, thus there is a problem in that a high vacuum gauge (pressure gauge) for pressure measurement deteriorates quickly.

### BRIEF DESCRIPTION OF THE DRAWINGS

FIG. 1 is a schematic diagram of a multi-beam writing apparatus according to an embodiment of the present invention.

FIG. 2 is a plan view of a shaping aperture array plate.

FIG. 3 is a graph showing a change in the internal pressure of a vacuum chamber according to a comparative example.

FIG. 4 is a flowchart illustrating a writing method according to the embodiment.

FIG. 5 is a graph showing an example of a change in the internal pressure of a vacuum chamber.

FIG. 6 is a view illustrating an example of a parameter setting screen.

### DETAILED DESCRIPTION

In one embodiment, an apparatus is for writing a pattern by irradiating a substrate as a writing target in a chamber with a charged particle beam. The apparatus includes a supply device supplying a cleaning gas to the chamber, a vacuum pump discharging a gas from the chamber, a pressure sensor detecting a pressure in the chamber, and a control device obtaining a detection value of the pressure sensor and controlling the supply device so that the pressure in the chamber reaches a first target value. When adjusting the charged particle beam with which the substrate is irradiated, the control device further controls the supply device so that the pressure in the chamber reaches a second target value different from the first target value.

Hereinafter, an embodiment of the present invention will be described based on the drawings. In the present embodiment, a configuration using an electron beam as an example of a charged particle beam will be described. The charged particle beam is not limited to the electron beam. For example, the charged particle beam may be an ion beam.

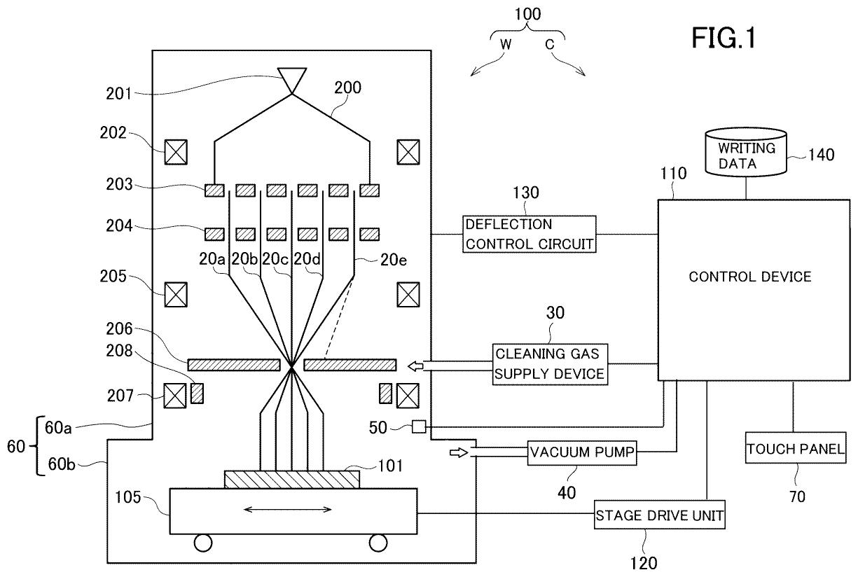

FIG. 1 is a schematic configuration diagram of a writing apparatus according to an embodiment. As illustrated in FIG. 1, a writing apparatus 100 includes a writer W and a control system C. The writing apparatus 100 is an example of a multi-charged particle beam writing apparatus. The writer W includes a vacuum chamber 60 consisting of an electron optical column 60a and a writing chamber 60b. The writing chamber 60b is a rectangular parallelepiped hollow member, and has a circular opening on the upper surface. The electron optical column 60a is a cylindrical casing having a longitudinal direction in the Z-axis direction, and is inserted into an opening formed on the upper surface of the writing chamber 60b.

In the electron optical column 60a, an electron gun 201, an illumination lens 202, a shaping aperture array plate 203, a blanking aperture array plate 204, a reduction lens 205, a limiting aperture member 206, an objective lens 207 and a deflector 208 are disposed.

In the writing chamber 60b, an XY stage 105 is disposed. A substrate 101 as a writing target is disposed on the XY stage 105. The substrate 101 is e.g., a mask blank or a semiconductor substrate (silicon wafer).

A pressure sensor 50 (high vacuum gauge) is disposed in the internal space of the vacuum chamber 60. The pressure sensor 50 outputs a voltage signal having a value corresponding to the pressure in the chamber.

The control system C has a control device 110, a stage drive unit 120, a deflection control circuit 130, a storage 140, a cleaning gas supply device 30, a vacuum pump 40, and a touch panel 70. Writing data is input from the outside, and stored in the storage 140. The writing data defines information on a plurality of figure patterns, the information describing patterns to be formed on the substrate 101. Specifically, the figure code, coordinates and size are defined for each figure pattern.

The control device 110 is a computer having a CPU, and controls the writer W, the stage drive unit 120, the deflection control circuit 130, the cleaning gas supply device 30, the vacuum pump 40 and the touch panel 70 in a comprehensive manner.

An electron beam 200 emitted from the electron gun 201 of the writer W illuminates the shaping aperture array plate 203 in its entirety by the illumination lens 202.

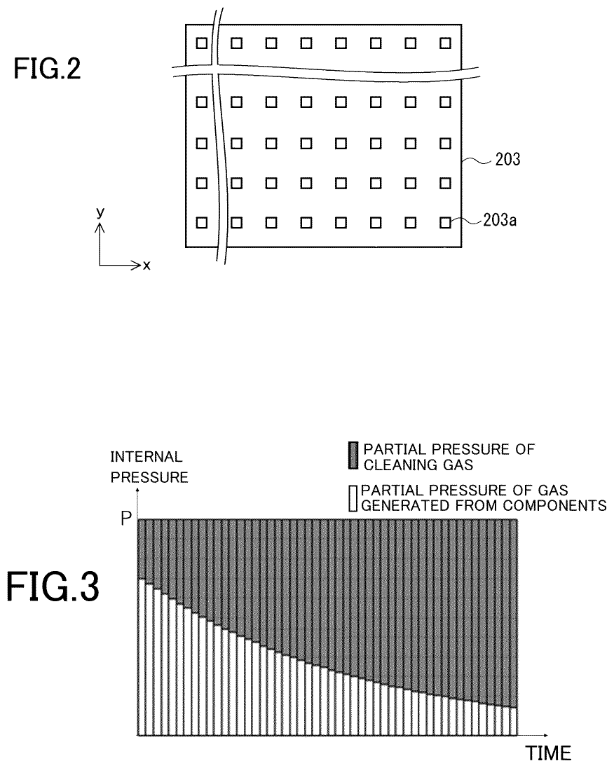

FIG. 2 is a conceptual view illustrating the configuration of the shaping aperture array plate 203. As illustrated in FIG. 2, in the shaping aperture array plate 203, a plurality of openings 203a are formed in the vertical direction (y direction) and the horizontal direction (x direction) with a predetermined arrangement pitch. It is preferable that the openings 203a be formed as rectangles or circles having the same dimensional shape. Multi-beams 20a to 20e are formed (discharged) by part of the electron beam 200 passing through a plurality of openings 203a.

Passage holes in the blanking aperture array plate 204 are formed corresponding to the arrangement positions of the openings 203a of the shaping aperture array plate 203. A blanker consisting of a set of two electrodes as a pair is disposed in each passage hole. One electrode of the blanker is grounded, and maintained at the ground potential, and the other electrode is switched to the ground potential or a potential other than the ground potential, thus deflection ON/OFF of the beam passing through each passage hole is switched, and blanking control is performed. When a beam is not deflected by a blanker, the beam is ON. When a beam is deflected by a blanker, the beam is OFF. In this manner, a plurality of blankers perform blanking deflection on corresponding beams in the multi-beam which have passed through the plurality of openings 203a of the shaping aperture array plate 203.

The multi-beams 20a to 20e which have passed through the blanking aperture array plate 204 are reduced by the reduction lens 205, and travel to an opening formed in the limiting aperture member 206.

Here, each beam controlled at a beam OFF state is deflected by a blanker, and travels along a trajectory passing through the outside of the opening of the limiting aperture member 206, thus is blocked by the limiting aperture member 206. In contrast, each beam controlled at a beam ON state is not deflected by a blanker, thus passes through the opening of the limiting aperture member 206. In this manner, blanking control is performed based on deflection ON/OFF of a blanker, and ON/OFF of the beam is controlled.

The multi-beams which have passed through the limiting aperture member 206 are focused by the objective lens 207, and form a pattern image with a desired reduction factor. The beams (the entire multi-beams) which have passed through the limiting aperture member 206 are collectively deflected by the deflector 208 in the same direction, and emitted to a desired position on the substrate 101.

When the XY stage 105 is continuously moved by the stage drive unit 120, at least during a period in which the substrate 101 is irradiated with a beam, the irradiation position of the beam is controlled by the deflector 208 so as to follow the movement of the XY stage 105. The multi-beams emitted at one time are ideally arranged with the pitch which is the product of the arrangement pitch of the plurality of openings 203a of the shaping aperture array plate 203 and the above-mentioned desired reduction factor.

The control device 110 virtually divides the writing region of the substrate 101 into a plurality of mesh regions. For example, the size of the mesh region is similar to the size of one individual beam included in the multi-beams, and each mesh region serves as a pixel (unit irradiation region). The control device 110 reads writing data from the storage 140, and calculates a pattern area density p of each pixel using the patterns defined in the writing data.

The control device 110 calculates an irradiation amount ρD₀ of the beam to be emitted to each pixel by multiplying the pattern area density ρ by a reference irradiation amount D₀. A correction factor for correcting proximity effect or the like may be further multiplied. The control device 110 divides the irradiation amount by the current amount of each of a plurality of individual beams included in the multi-beams, thereby calculating the irradiation time of each of the plurality of individual beams.

The control device 110 rearranges irradiation time data in a shot order in a writing sequence to generate irradiation time control data, and outputs the irradiation time control data to the deflection control circuit 130. The deflection control circuit 130 outputs the irradiation time control data to the blanking aperture array plate 204. An input/output circuit of the blanking aperture array plate 204 transfers the irradiation time data to corresponding blankers.

The plurality of individual beams included in the multi-beams expose different pixels simultaneously, and turns on each beam for a necessary time for the beam to provide a desired exposure amount for each pixel.

In the multi-beam writing, beam adjustment such as focusing is important. For example, using the technique described in Japanese Unexamined Patent Application Publication No. 2018-82120, an optimal lens value (excitation current value) of the objective lens 207 is determined, and focusing is performed. Adjustment of the reduction factor of multi-beam using the technique described in Japanese Unexamined Patent Application Publication No. 2017-199758, or deflection sensitivity adjustment using the technique described in Japanese Unexamined Patent Application Publication No. 10-284392 may be performed. The beam adjustment is performed at predetermined time intervals.

The cleaning gas supply device 30 is coupled to the vacuum chamber 60 via a pipe, and has a cleaning gas generator, and a flow rate adjustment valve that regulates the amount of introduction of the cleaning gas to the vacuum chamber 60. The cleaning gas supply device 30 supplies a cleaning gas to the inside of the vacuum chamber 60 with a flow rate specified by the control device 110. The cleaning gas is e.g., ozone gas.

The vacuum pump 40 exhausts the gas inside the vacuum chamber 60 based on instructions of the control device 110, and maintains the inside of the vacuum chamber 60 at a predetermined pressure or lower.

The control device 110 obtains a measured value of the pressure sensor 50 in a predetermined period to reduce focus deviation of the multi-beam, and controls the cleaning gas supply device 30 and the vacuum pump 40 so that the internal pressure of the vacuum chamber 60 becomes constant. For example, the control device 110 controls the valve opening degree of the cleaning gas supply device 30, and the start and stop of the vacuum pump 40 based on the measured values of the pressure sensor 50. The gas generated from the components such as the blanking aperture array plate 204 in the vacuum chamber 60 gradually decreases with a lapse of time. When the internal pressure of the vacuum chamber 60 is controlled at a constant value P as illustrated in FIG. 3, the amount of introduction of the cleaning gas to the vacuum chamber 60 gradually increases, thus the partial pressure of the cleaning gas in the vacuum chamber 60 gradually increases. In the graph of FIG. 3, the gray portion indicates the partial pressure of the cleaning gas, the white portion indicates the partial pressure of the gas generated from the components in the chamber, and the pressure in the chamber is the total of these partial pressures.

The multi-beam writing apparatus includes a great number of components in the vacuum chamber 60, so has a large amount of generated gas, particularly at the start of drive, thus has a high initial internal pressure, and target value P for constant pressure control is also high. When a state of a high internal pressure of the vacuum chamber 60 continues, the pressure sensor 50 deteriorates early.

Thus, in this embodiment, the target value for the constant pressure control is reduced at a timing of beam adjustment. When the target value for the constant pressure control is reduced, the internal pressure of the vacuum chamber 60 is changed; however, focus deviation of the multi-beam is reduced because the beam adjustment is performed.

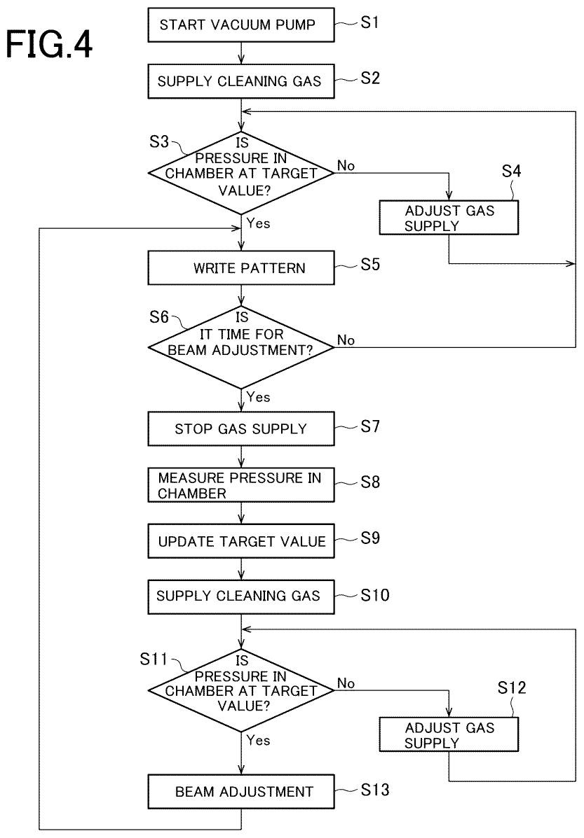

A multi-beam writing method according to this embodiment will be described based on the flowchart illustrated in FIG. 4.

The control device 110 starts the vacuum pump 40 (step S1). The gas inside the vacuum chamber 60 is exhausted, thus the pressure inside the chamber reduces.

The cleaning gas supply device 30 supplies the cleaning gas into the vacuum chamber 60 (step S2).

The control device 110 controls the cleaning gas supply device 30 to adjust the amount of gas supply based on the measured values of the pressure sensor 50 so that the internal pressure of the vacuum chamber 60 reaches a predetermined target value (within a target range) (step S3_No, S4). The target value is based on the internal pressure of the vacuum chamber 60 before the start of supply of the cleaning gas. For example, the target value is a value obtained by adding a predetermined value or multiplying a predetermined factor to or by the internal pressure of the vacuum chamber 60 before the start of supply of the cleaning gas. A predetermined addition value or factor can be set by a user in any manner through operation of the touch panel 70.

For example, a parameter setting screen as illustrated in FIG. 6 is displayed on the touch panel 70. A user presses a touch key 73 to set a predetermined addition value (partial pressure (B) of the cleaning gas) in advance. The internal pressure of the vacuum chamber 60 before the start of supply of the cleaning gas is displayed on a display field 72. The target value is displayed on a display field 74.

Multi-beams are formed and emitted to the substrate 101 to write a desired pattern by the above-described method while the pressure in the chamber is controlled to be constant at a target value (step S3_Yes, S5). The detection value (measurement value) of the pressure sensor 50 is displayed in real time on a display field 71 of the parameter setting screen.

When the timing for beam adjustment is reached (step S6_Yes), supply of the cleaning gas from the cleaning gas supply device 30 is stopped (step S7).

The control device 110 obtains, from the pressure sensor 50, the internal pressure of the vacuum chamber 60 after a lapse of a predetermined time (e.g., approximately three minutes) since supply of the cleaning gas has been stopped (step S8). At this point, the cleaning gas has been substantially exhausted from the vacuum chamber 60 by the vacuum pump 40, and the pressure in the chamber measured by the pressure sensor 50 comes from the gas (corresponding to the white portion of the graph in FIG. 3) generated from the components in the chamber.

The control device 110 calculates a new target value for the pressure in the chamber to update the previous target value based on the pressure measured in step S8 (step S9). A new target value is calculated, for example, by adding a predetermined value or multiplying a predetermined factor to or by the pressure measured in step S8. The pressure measured in step S8 is displayed on the display field 72 of the parameter setting screen. A new target value obtained by adding the partial pressure (B) of the cleaning gas set via the touch key 73 to the measured pressure is displayed on the display field 74.

The supply of the cleaning gas is resumed (step S10), and controls the cleaning gas supply device 30 to adjust the amount of gas supply so that the internal pressure of the vacuum chamber 60 reaches the updated target value (step S11_No, S12).

When the pressure in the chamber reaches the target value (step S11_Yes), beam adjustment is performed (step S13). In the beam adjustment, focusing, reduction factor adjustment, deflection sensitivity adjustment and the like are performed. After the beam adjustment, pattern writing is resumed.

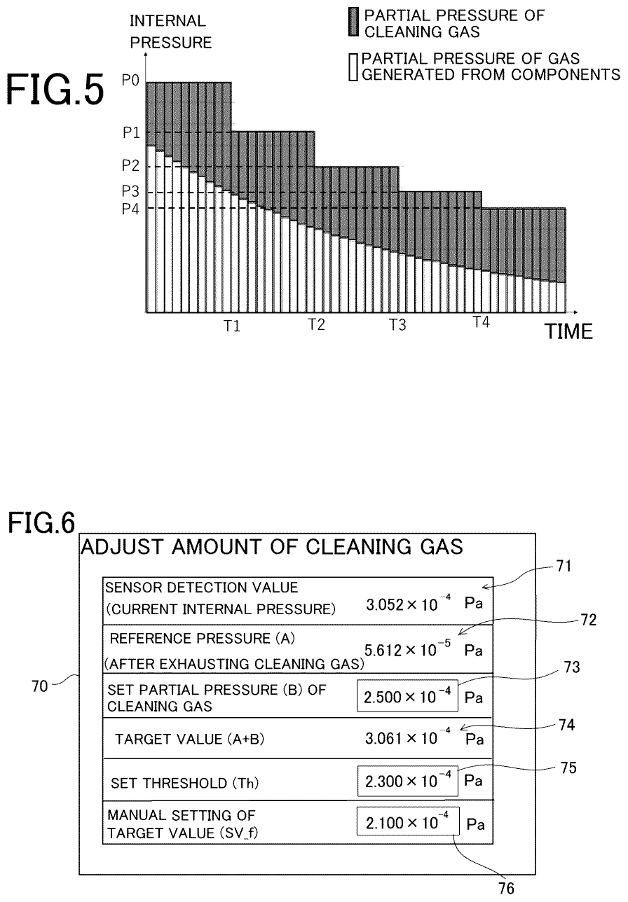

FIG. 5 shows an example of a change in the internal pressure of the vacuum chamber 60. In this example, the first target value for constant internal pressure control of the vacuum chamber 60 is P0. When timing T1 for the beam adjustment is reached, the cleaning gas is exhausted, the pressure in the chamber is measured, and the target value is updated to a new target value P1. Since the amount of gas generated from the components in the chamber has decreased, the target value P1 after the update is smaller in value than the target value P0 before the update.

The pressure in the chamber is controlled at P1 until the next timing T2 for the beam adjustment is reached. When the timing T2 for the beam adjustment is reached, the cleaning gas is exhausted, the pressure in the chamber is measured, and the target value is updated to a new target value P2. Since the amount of gas generated from the components in the chamber has decreased, the target value P2 after the update is smaller in value than the target value P1 before the update.

The pressure in the chamber is controlled at P2 until the next timing T3 for the beam adjustment is reached.

In this manner, in this embodiment, according to the reduction in the amount of gas generated from the components in the chamber, the target value for the constant pressure control for the vacuum chamber 60 is gradually reduced for each timing of the beam adjustment. The internal pressure of the vacuum chamber 60 is changed by decreasing the target value for the constant pressure control; however, focus deviation of the multi-beam is reduced because the beam adjustment is performed.

Since the internal pressure of the vacuum chamber 60 decreases at each timing of the beam adjustment, a high internal pressure state of the vacuum chamber 60 does not continue, thus deterioration of the pressure sensor 50 can be prevented, and the life can be extended.

In addition, the amount of supply of the cleaning gas to the vacuum chamber 60 can be reduced.

In the embodiment, an example has been described in which the target value for the constant pressure control is automatically calculated and updated by adding a predetermined value (a first predetermined value) to the pressure in the chamber after exhaustion of the cleaning gas; however, when the calculated target value for the constant pressure control is less than a predetermined threshold (a second predetermined value), a value (a third predetermined value) set by a user in advance may serve as a new target value. Consequently, excessive reduction in the target value for the constant pressure control can be prevented.

A user can set any threshold (Th) by pressing a touch key 75 on the parameter setting screen illustrated in FIG. 6. In addition, a user can manually set a target value (SV_f) for the pressure in the chamber by pressing a touch key 76.

When the timing for the beam adjustment is reached, a new target value is calculated by adding the partial pressure (B) of the cleaning gas set by a user to the internal pressure (A) after exhaustion of the cleaning gas, and is displayed on the display field 73.

When the calculated target value is less than a threshold (Th) set in advance, the target value for the constant pressure control is the target value (SV_f) set by a user. Hereinafter, automatic calculation and update processes (step S7 to S12) of the target value are skipped, and the target value becomes constant.

At the timing of the beam adjustment, the components in the vacuum chamber 60, such as the blanking aperture array plate 204 may be replaced. In this case, the generated gas increases due to the component replacement, the pressure measured in step S8 may increase, and a new target value calculated by adding a predetermined value or multiplying a predetermined factor may be higher than the previous target value (before the component replacement).

Note that when the previous target value is the target value (SV_f) set by a user, and the new target value calculated after the component replacement is also less than or equal to the target value (SV_f) set by a user, the target value does not need to be changed (SV_f is left as it is).

Although a writing apparatus using multiple beams has been described in the embodiment, the writing apparatus may be one that uses a single beam.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. An apparatus for writing a pattern by irradiating a substrate as a writing target in a chamber with a charged particle beam, the apparatus comprising:
a supply device supplying a cleaning gas to the chamber;
a vacuum pump discharging a gas from the chamber;
a pressure sensor detecting a pressure in the chamber; and
a control device obtaining a detection value of the pressure sensor and controlling the supply device so that the pressure in the chamber reaches a first target value,
wherein when adjusting the charged particle beam with which the substrate is irradiated, the control device further controls the supply device so that the pressure in the chamber reaches a second target value different from the first target value.

2. The apparatus according to claim 1,
wherein before adjusting the charged particle beam, the control device controls the supply device to stop supply of the cleaning gas, and calculates the second target value based on the detection value of the pressure sensor after a lapse of a predetermined time since supply of the cleaning gas has been stopped.

3. The apparatus according to claim 2,
wherein before adjusting the charged particle beam, the control device controls the supply device to stop supply of the cleaning gas, and calculates the second target value by adding a predetermined value to the detection value of the pressure sensor after a lapse of a predetermined time since supply of the cleaning gas has been stopped.

4. The apparatus according to claim 2,
wherein before adjusting the charged particle beam, the control device controls the supply device to stop supply of the cleaning gas, and when a value obtained by adding a first predetermined value to the detection value of the pressure sensor after a lapse of a predetermined time since supply of the cleaning gas has been stopped is less than a second predetermined value, the control device sets the second target value to a third predetermined value.

5. The apparatus according to claim 1,
wherein the second target value is smaller than the first target value.

6. The apparatus according to claim 1,
wherein the adjustment of the charged particle beam includes focusing, deflection sensitivity adjustment, or adjustment of a reduction factor of multi-beam.

7. A method for writing a pattern by irradiating a substrate as a writing target in a chamber with a charged particle beam, the method comprising:
supplying a cleaning gas to the chamber;
discharging a gas from the chamber;
detecting a pressure in the chamber by a pressure sensor;
controlling an amount of supply of the cleaning gas based on a detection value of the pressure sensor so that the pressure in the chamber reaches a first target value; and
performing adjustment on the charged particle beam with which the substrate is irradiated,
wherein when the adjustment is performed, the amount of supply of the cleaning gas is controlled so that the pressure in the chamber reaches a second target value different from the first target value, and
after the adjustment, the amount of supply of the cleaning gas is controlled so that the pressure in the chamber keeps the second target value.

8. The method according to claim 7,
wherein supply of the cleaning gas is stopped, and
the second target value is calculated based on the detection value of the pressure sensor after a lapse of a predetermined time since supply of the cleaning gas has been stopped.

9. The method according to claim 8,
wherein the second target value is calculated by adding a predetermined value to the detection value of the pressure sensor after a lapse of a predetermined time since supply of the cleaning gas has been stopped.

10. The method according to claim 8,
wherein when a value obtained by adding a first predetermined value to the detection value of the pressure sensor after a lapse of a predetermined time since supply of the cleaning gas has been stopped is less than a second predetermined value, the second target value is set to a third predetermined value.

11. The apparatus according to claim 7,
wherein the second target value is smaller than the first target value.

12. The apparatus according to claim 7,
wherein the adjustment of the charged particle beam includes focusing, deflection sensitivity adjustment, or adjustment of a reduction factor of multi-beam.
